(19) United States
(12) Patent Application Publication
(10) Pub. No.: US 2012/0292740 A1
(43) Pub. Date: Nov. 22, 2012

(54) HIGH VOLTAGE RESISTANCE SEMICONDUCTOR DEVICE AND METHOD OF MANUFACTURING A HIGH VOLTAGE RESISTANCE SEMICONDUCTOR DEVICE

(75) Inventors: Chen-Yuan Lin, Taitung (TW); Cheng-Chi Lin, Yilan County (TW); Shih-Chin Lien, Sinjhuang (TW); Chin-Pen Yeh, Hsinchu (TW)

(73) Assignee: MACRONIX INTERNATIONAL CO., LTD., Hsinchu (TW)

(21) Appl. No.: 13/111,563

(22) Filed: May 19, 2011

(51) Int. Cl. H01L 29/02; H01L 21/02

(52) U.S. Cl. 257/536; 438/382; 257/E29.002; 257/E21.004

(57) ABSTRACT

A semiconductor device comprises a semiconductor substrate, a lateral semiconductor diode, a field insulation structure, and a polysilicon resistor. The diode is formed in a surface region of the semiconductor substrate, and includes a cathode electrode and an anode electrode. The field insulation structure is disposed between the cathode and anode electrodes. The polysilicon resistor is formed over the field insulation structure, and between the cathode and anode electrodes. The polysilicon resistor is electrically connected to the cathode electrode, and electrically insulated from the anode electrode.

### BACKGROUND

1. Technical Field

The present application relates to semiconductor technology, and more particularly to semiconductor devices suitable for providing a high voltage resistance.

2. Related Art

Semiconductor high voltage (HV) diodes such as the HV diode 100 shown in FIG. 1A are known, for example for use in high-voltage drivers or the like in semiconductor devices. The diode 100 includes a cathode 102 and an anode 104. Conventional practice is to arrange the cathode in parallel with a polysilicon resistor 110 for isolation purposes. FIG. 1B shows an equivalent circuit diagram of the diode 100 and resistor 110 shown in FIG. 1A. A high-voltage input 112 is typically provided to the cathode 102 of the diode 100 between the cathode 102 and the resistor 110.

As shown in FIG. 1A, the polysilicon resistor 110 is typically formed in a pattern that includes a series of elongated strips that are connected together to form a polysilicon structure that has a length that is selected according to a desired resistance. As a result, the conventional resistor 110 shown in FIG. 1A occupies some portion 114 of the layout area of a semiconductor device that is in addition to the layout area of the diode 100. It would therefore be desirable to eliminate the need for the additional layout area 114 occupied by the resistor 100 so that the size of a semiconductor layout including an HV diode can be reduced.

### SUMMARY

Semiconductor devices and methods associated with semiconductor devices are described herein. According to one aspect of the present disclosure, a semiconductor device can comprise a semiconductor substrate, and a lateral semiconductor diode formed in a surface region of the semiconductor substrate. The diode can have a cathode electrode and an anode electrode. A field insulation structure can be disposed between the cathode and anode electrodes, and a polysilicon resistor can be formed over the field insulation structure and between the cathode and anode electrodes. The polysilicon resistor can be electrically connected to the cathode electrode and electrically insulated from the anode electrode.

In some embodiments, the polysilicon resistor can be formed on an upper surface of the field insulation structure to at least partially surround the cathode electrode. The polysilicon resistor can include a plurality of semicircular segments concentrically arranged between the cathode and anode electrodes. The segments can include at least one innermost segment that is electrically connected to the cathode electrode. Adjacent segments can be electrically connected so as to form a continuous polysilicon resistor structure from the cathode electrode to a terminal external to the semiconductor diode.

In some embodiments, the anode electrode can include a circular structure surrounding the cathode electrode.

In some embodiments, the polysilicon resistor can include a plurality of semicircular segments arranged in a coaxial pattern, and the semicircular segments can be surrounded by the anode electrode.

According to another aspect of the present disclosure, a method of manufacturing a semiconductor device can comprise providing a semiconductor substrate, and forming a lateral semiconductor diode in a surface region of the semiconductor substrate. The forming of the lateral semiconductor diode can include forming a cathode electrode and forming an anode electrode. The method can also include forming a field insulation structure between the cathode and anode electrodes, and forming a polysilicon resistor over the field insulation structure and between the cathode and anode electrodes. The forming of the polysilicon resistor can include forming the polysilicon resistor to be electrically connected to the cathode electrode and electrically insulated from the anode electrode.

In some embodiments, the forming of the polysilicon resistor can include forming the polysilicon resistor on an upper surface of the field insulation structure to at least partially surround the cathode electrode. The forming of the polysilicon resistor can include forming the polysilicon resistor to includes a plurality of semicircular segments concentrically arranged between the cathode and anode electrodes. The forming of the polysilicon resistor can include forming the segments to include at least one innermost segment that is electrically connected to the cathode electrode. The forming of the polysilicon resistor can include forming adjacent segments to be electrically connected so as to form a continuous polysilicon resistor structure from the cathode electrode to a terminal external to the semiconductor diode.

In some embodiments, the forming of the anode electrode includes forming a circular structure as the anode electrode surrounding the cathode electrode.

In some embodiments, the forming of the polysilicon resistor can include forming the polysilicon resistor to include a plurality of semicircular segments arranged in a coaxial pattern, and the semicircular segments can be surrounded by the anode electrode.

These and other features, aspects, and embodiments are described below in the section entitled “Detailed Description.”

### BRIEF DESCRIPTION OF THE DRAWINGS

Features, aspects, and embodiments of the inventions are described in conjunction with the attached drawings, in which:

FIG. 1A shows a plan view of a conventional HV diode and polysilicon resistor device;

FIG. 1B shows a circuit diagram corresponding to the device shown in FIG. 1A;

FIG. 2 shows a plan view of an HV diode and polysilicon resistor device according to the present disclosure;

FIGS. 3A and 3B show a circuit diagrams corresponding to embodiments of the device shown in FIG. 2;

FIG. 4A shows a cross-sectional view taken along section lines A-A in FIG. 2;

FIG. 4B shows a cross-sectional view taken along section lines B-B in FIG. 2;

FIG. 5 shows a partial plan view of an embodiment of a polysilicon resistor; and

FIGS. 6A-6O show intermediate structures corresponding to a process for manufacturing the disclosed semiconductor device.

### DETAILED DESCRIPTION

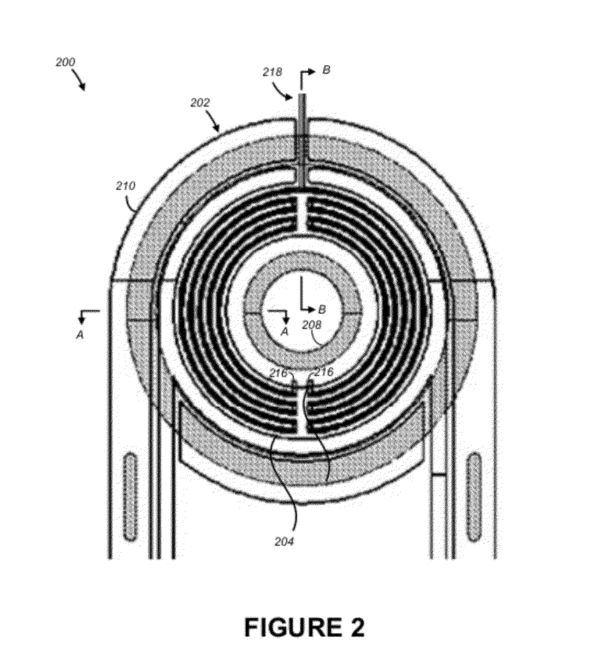

A detailed description of embodiments of the present application is provided with reference to the FIGS. 2-6O.

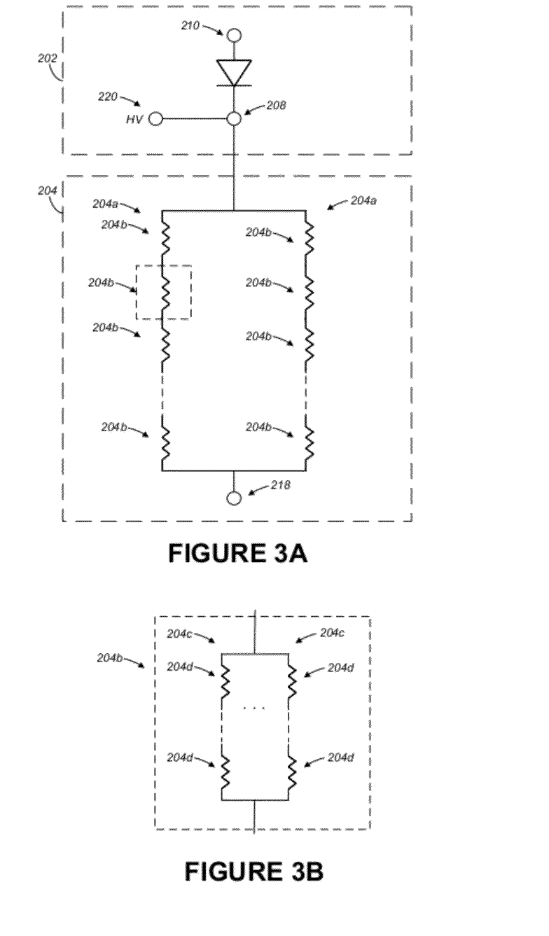

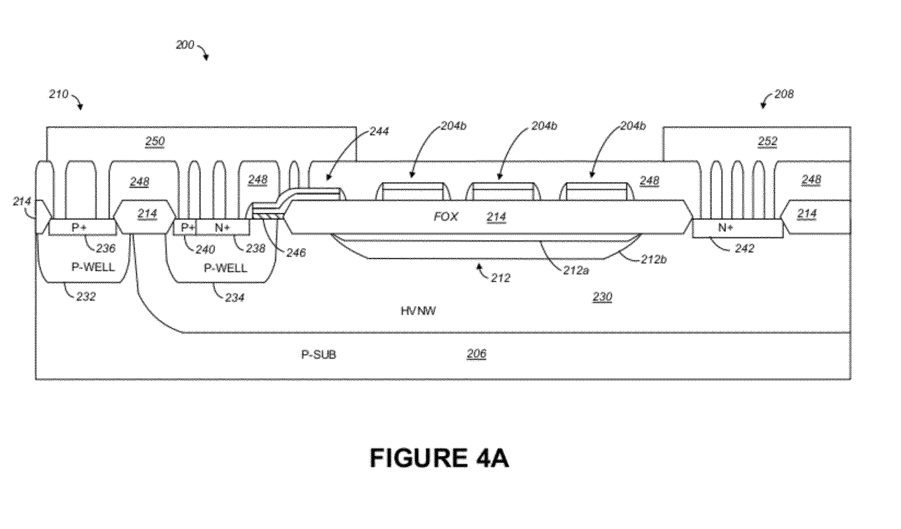

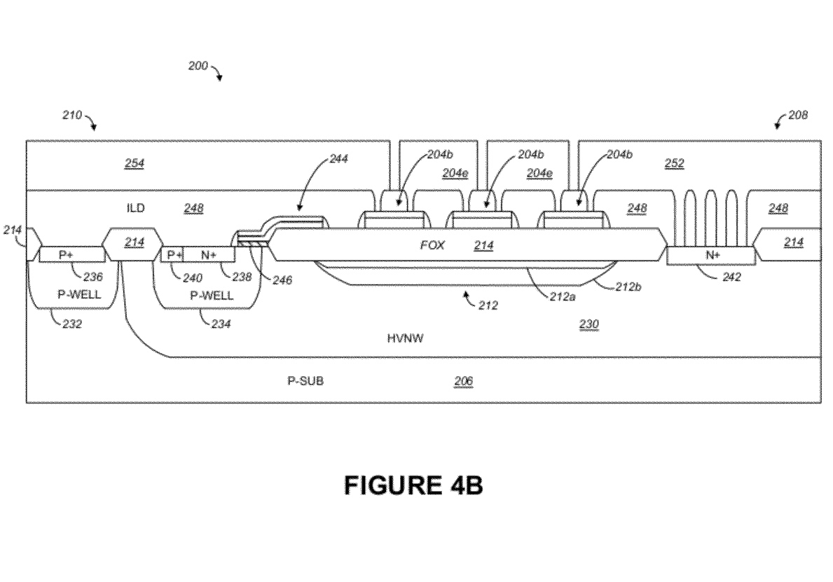

FIG. 2 shows a plan view of a semiconductor device 200 that includes an HV diode 202 and a polysilicon resistor 204. FIGS. 3A-3B show equivalent circuit diagrams for the semiconductor device 200. FIG. 4A shows a cross-sectional view of the semiconductor device 200 taken along section lines A-A in FIG. 2. FIG. 4B shows a cross-sectional view of the semiconductor device 200 taken along section lines B-B in FIG. 2.

Referring primarily to FIG. 2, the diode 202 is a lateral semiconductor device that is formed in a surface region of a semiconductor substrate 206 (shown in FIGS. 4A and 4B). The diode 202 includes a central cathode electrode 208 surrounded by an anode electrode 210. The cathode electrode 208 can be a circular disc-shaped electrode and the anode electrode 210 can be a circular electrode that coaxially surrounds the cathode electrode 208. The cathode electrode 208 and anode electrode 210 are separated by a drift region 212 (shown in FIGS. 4A and 4B), which controls the flow of electrical current between the cathode and anode electrodes 208 and 210 in a manner consistent with known diodes.

The resistor 204 is disposed above the drift region 212, in the space provided between the cathode and anode electrodes 208 and 210. More specifically, as shown in FIGS. 4A and 4B, the resistor 204 can be formed of a series of polysilicon structures 204a that are disposed over a field oxide (FOX) structure 214, which in turn is disposed over the drift region 212. Note that while the resistor 204 is shown to be formed directly on an upper surface of the FOX structure 214, alternative arrangements are possible, for example where one or more additional layers are disposed between the FOX structure 214 and the resistor 204. The resistor 204 is electrically connected to the cathode electrode 208 at contacts 216. The resistor 204 is electrically insulated from the anode electrode 210, but extends over the anode electrode 210 to a terminal 218 for connection to other devices.

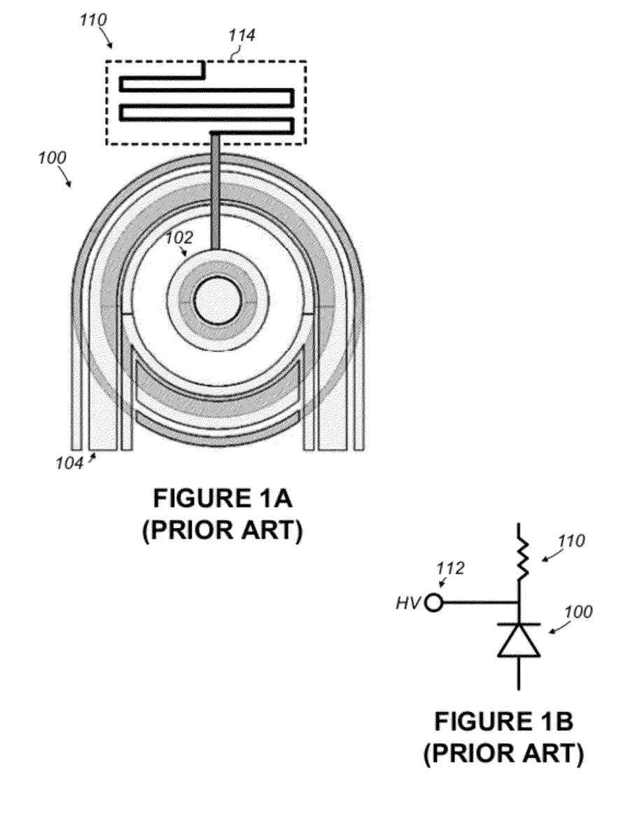

The resistor 204 can thus be formed on an upper surface of the FOX structure 214 the resistor 204 at least partially surrounds the cathode electrode 208, and the resistor 204 is also at least partially surrounded by the anode electrode 210. This arrangement advantageously allows the resistor 204 to be provided with the device 200 without occupying an excess layout region external to the diode 202, which is in contrast with the resistor 110 shown in FIG. 1A, which occupies the additional layout area 114.

FIG. 3A shows an equivalent circuit diagram of the semiconductor device 200. The diode 202 is connected in parallel with the resistor 204, such that the resistor 204 is provided between the cathode electrode 208 and external terminal 218. The cathode electrode 208 is also electrically connected to a high voltage (HV) terminal 220.

In the layout shown in FIG. 2, the resistor 204 is composed of a pair of polysilicon resistor structures 204a that are connected to each other in parallel between the cathode electrode 208 and the external terminal 218. Each polysilicon resistor structure 204a is composed of a series of concentric semi-circular resistor segments 204b, where each segment 204b is represented in FIG. 3A as an individual resistor. In the embodiment shown in FIG. 2, innermost resistor segments 204b can be connected to the cathode electrode 208, while the outermost resistor segments 204b can be connected to the external terminal 218. Adjacent resistor segments 204b between the innermost and outermost segments 204b are connected together to form two parallel series of resistors between the cathode electrode 208 and the external terminal 218.

As shown in FIG. 3B, one or more of the segments 204b can, optionally, be further broken down into a series of two or more parallel resistor sub-structures 204c, each composed of some number of resistor sub-segments 204d, by changing the design of the layout. Those skilled in the art will appreciate that such changes can allow for fine-tuning the overall resistance of the resistor 204. It should be noted that the exact number of resistor structures 204a, segments 204b, sub-structures 204c, and sub-segments 204d can vary from the number provided for the embodiments illustrated by figures.

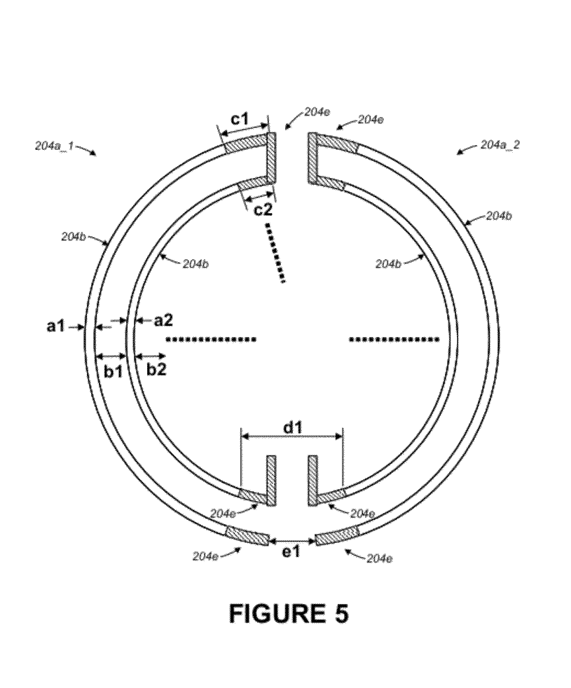

FIG. 5 shows a plan view of a portion of the resistor 204. More specifically,

FIG. 5 shows a pair of segments 204b of each of a pair the resistor structures 204a, separately identified in FIG. 5 as 204a_1 and 204a_2. The view shown in FIG. 5 more clearly illustrates how the segments 204b can be laid out as a series of concentric semi-circular polysilicon structures. Each structure can have a predetermined width a1 or a2, where a1 can equal a2 or a1 can differ from a2 according to a desired overall resistance value of the resistor 204, as well as other considerations such as layout constraints. Spacing between concentrically-adjacent segments 204b can be selected according to design constraints, for example to prevent shorting during fabrication processes. The segments 204b are connected to each other by metal contact regions 204e.

The dimensions c1 and c2 represent respective lengths of metal structures that form portions of the contact regions 204e, the dimension d1 represents the distance between neighboring ends of polysilicon structures of the resistor segments 204b, and the dimension e1 represents the distance between neighboring contact structures 204e of the resistor segments 204b. The resistor structures 204a_1 and 204a_2 are equidistant from the cathode electrode 208 and therefore constitute opposing corresponding resistor structures 204a. Preferrably, each such opposing corresponding pair of resistor structures 204a should be symmetric, such that the dimensions are the same for each of the opposing corresponding pair of resistor structures 204a.

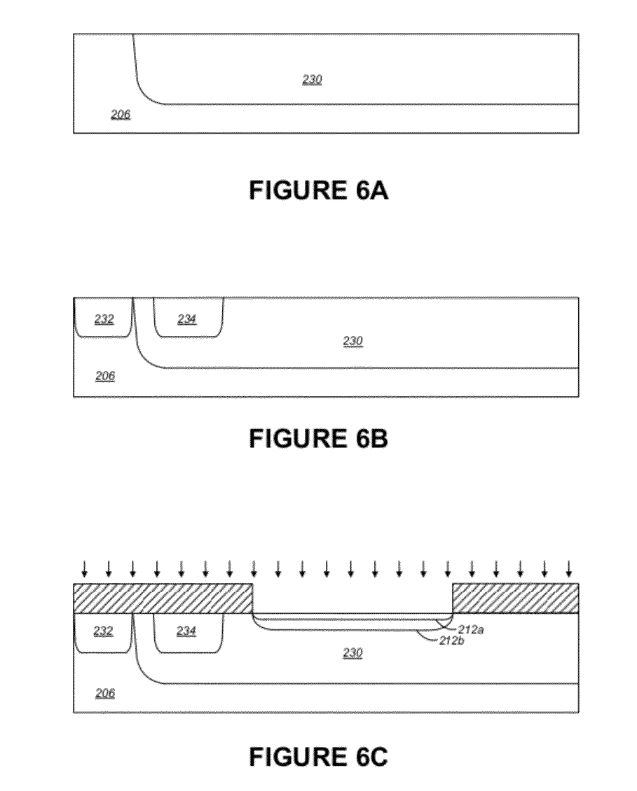

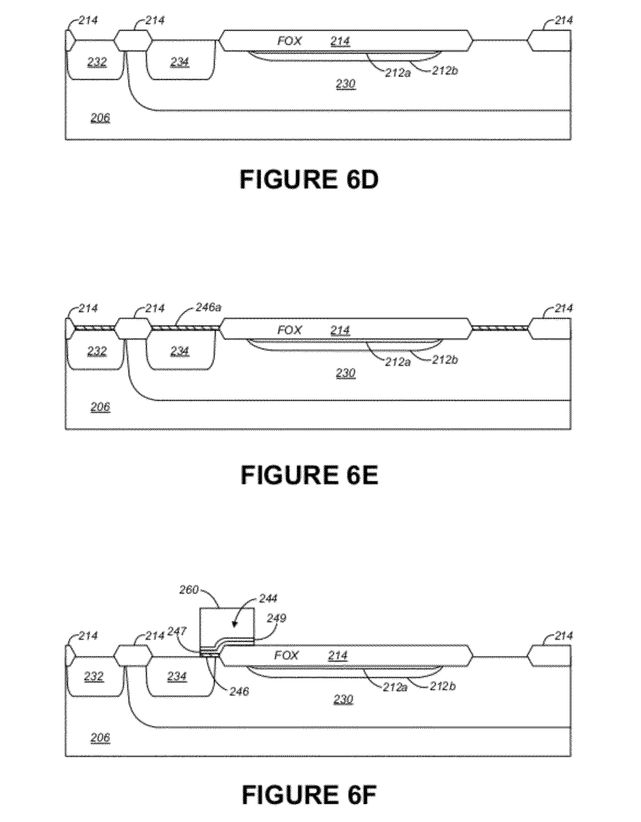

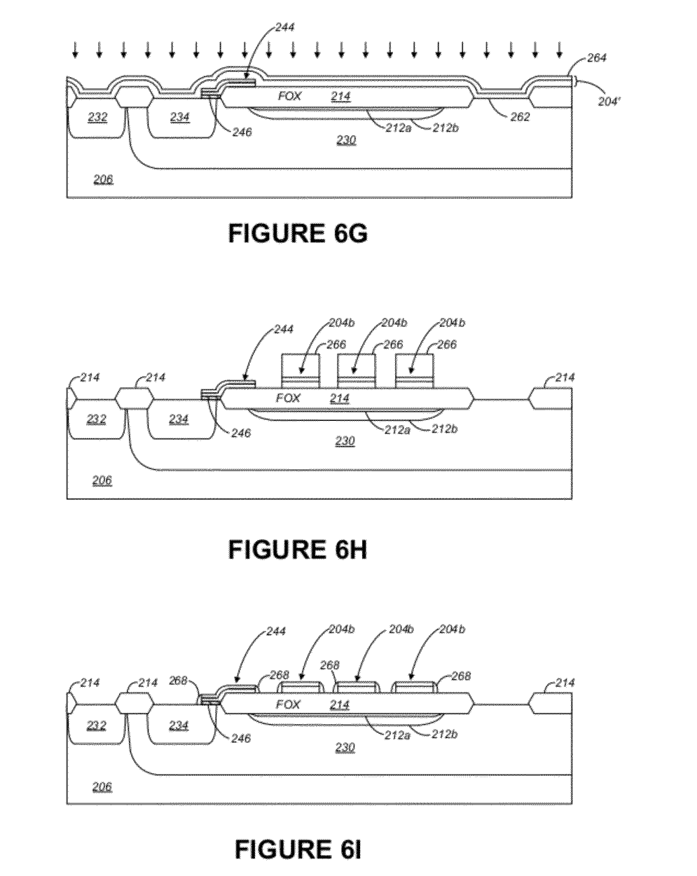

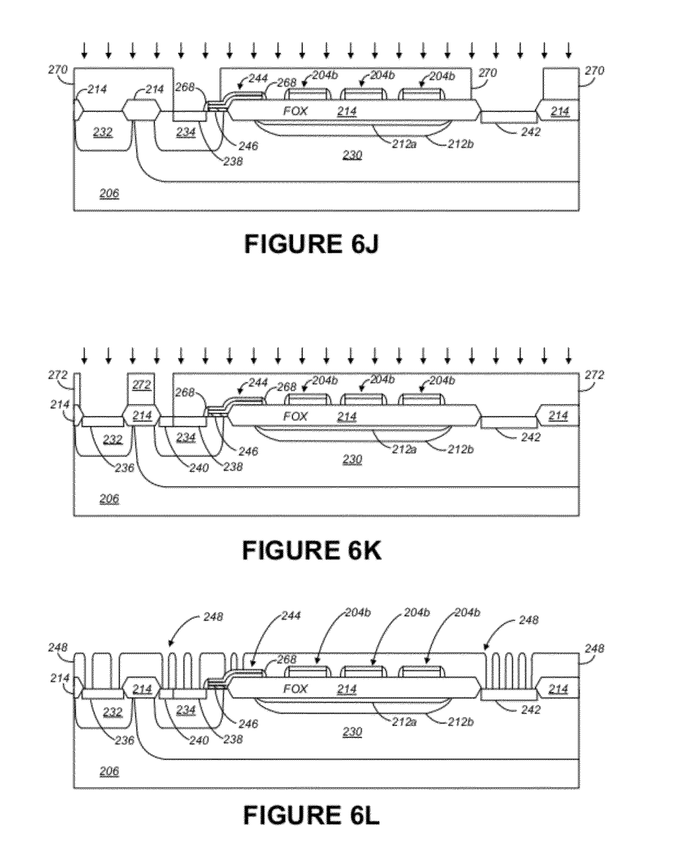

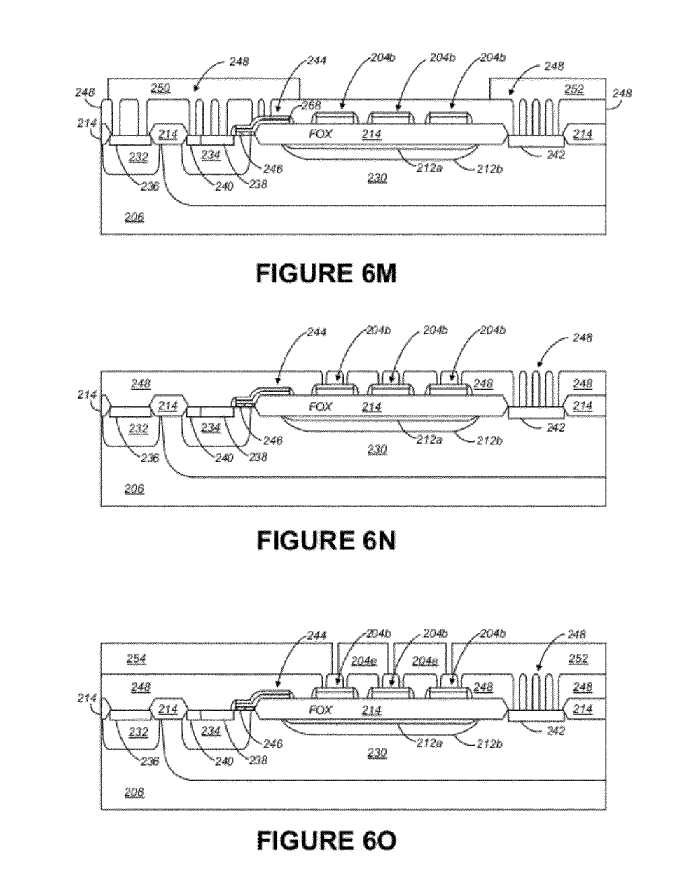

Referring now specifically to FIGS. 4A and 4B, will next be described, followed by a description of an embodiment of a manufacturing process (shown in FIGS. 6A-6O) that can be used to manufacture the semiconductor device 200.

FIG. 4A shows a cross-sectional view of the semiconductor device 200 taken along section lines A-A in FIG. 2. FIG. 4B shows a cross-sectional view of the semiconductor device 200 taken along section lines B-B in FIG. 2.

The semiconductor device 200 can be formed on a semiconductor substrate 206, typically silicon, of a first conductivity type, typically P-type conductivity. A drift channel 212 of a second conductivity type, typically N-type conductivity, is formed in a high-voltage n-well (HVNW) region 230 of the substrate 206. The drift channel 212 can include an n-type surface region 212a that is separated from the HVNW region 230 by a p-type liner 212b.

The anode region 210 includes a first P-type well 232 and a second P-type well 234. The first P-type well 232 is formed in the substrate 206, and the second P-type well 234 is formed in the HVNW region 230. A P+ buried diffusion region 236 is formed in the first P-type well 232. An N+ buried diffusion region 238 is formed in the second P-type well 234. In addition, a P+ pickup region 240 is formed in the second P-type well 234 adjacent to the N+ buried diffusion region 238. The cathode region 208 includes an N+ buried diffusion region 242 formed in the HVNW region 230.

A multi-layer gate structure 244 includes a gate oxide layer 246 and one or more additional gate layers, which can include, for example, a polysilicon layer 247 over the gate oxide layer 246, and a tungsten silicide (WSi) layer 249 over the polysilicon layer 247. A portion of the gate structure 244, referred to as a field plate, extends over the FOX structure 214. The FOX structure 214 is a relatively thick insulating region that extends between the cathode 208 and anode 210. Additional FOX regions 214 are also formed as needed to serve as isolation structures, for example at the edges of the device 200 and between the first and second P-wells 232 and 234.

FIGS. 4A and 4B also show the resistor segments 204b, which are formed on the upper surface of the FOX structure 214 between the cathode 208 and the anode 210. The resistor segments 204b can be single or multi-layer polysilicon structures. The resistor segments 204b are electrically insulated from each other in the view shown in FIG. 4A by an inter-layer dielectric (ILD) structure 248. The view shown in FIG. 4B shows the metal structures that serve as contact regions 204e, which electrically connect adjacent resistor segments 204b.

FIG. 4A shows an anode contact region 250 and a cathode contact region 252. The anode contact region 250 is an electrically conductive material, typically metal, that provides an electrical connection to the buried diffusion regions 236, 238, and 240, as well as to the gate structure 244. The cathode contact region 252 is also an electrically conductive material, typically metal, that provides an electrical connection to the buried diffusion region 242.

The view shown in FIG. 4B shows how the cathode contact region 252 also provides the electrical connection between the cathode 208 and the resistor 204 by connecting the buried diffusion region 242 to the innermost resistor segment 204b. FIG. 4B also shows a resistor contact region 254, which provides the electrical connection between the outermost resistor segment 204b and the external terminal 218 (shown in FIG. 2).

Turning next to FIGS. 6A-6O, an example of a manufacturing process will be described that is suitable for constructing the semiconductor device 200. The views shown in FIGS. 6A-6K are the same for the cross-sectional views taken along section lines A-A and along section lines B-B in FIG. 2. FIGS. 6L and 6M show metallization processes along section lines A-A, while FIGS. 6N and 6O show metallization processes along section lines B-B.

Beginning with a P-type silicon substrate 206 at FIG. 6A, the HVNW region 230 is first formed, for example using known photolithography and HVNW implant processes. Next, at FIG. 6B, the first and second P-type wells 232 and 234 are formed, again by way of known photolithography and ion implanting processes. At FIG. 6C, the n-type surface region 212a and p-type liner 212b are formed according to known photolithography and ion implantation processes. Next, FIG. 6D shows the result of photolithography, oxidation, and etching processes that can be used to form the FOX regions 214.

Next, the gate structure 244 is formed by processes illustrated in FIGS. 6E and 6F. FIG. 6E shows an oxide layer 246a, which will become the gate oxide layer 246. The oxide layer 246a can be formed using a SAC (sacrificial oxidation) process. Next, deposition processes are used to deposit a polysilicon layer 247 over the oxide layer 246a, then to deposit the WSi layer 249 over the polysilicon layer 247. A photomask layer 260 is then selectively deposited over the WSi layer 249, and subsequent etching results in the structure shown in FIG. 6F.

The process of forming the resistor 204 begins next at FIG. 6G. The resistor segments 204b can be multi-layer structures that include, for example, lower oxide layer and an upper polysilicon layer. To form such a structure, a high-temp oxidation (HTO) process, such as typically used for formation of PIP capacitor structures, can be used to form the lower oxide layer 262, and then a subsequent PIP polysilicon deposition process can be used to deposit the polysilicon layer 264 over the oxide layer 262. As illustrated in FIG. 6G, the conductivity of the polysilicon layer 264 can be adjusted by ion implantation processes for doping the polysilicon layer 264. The resulting structure is then etched using photolithography processes to form the resistor segments 204b as shown in FIG. 6H, which also shows photo masking material 266. Spacers 268 shown in FIG. 6I can be formed on sidewalls of the resistor segments 204b and sidewalls of the gate structure 244 using tetra-ethyl-ortho silicate (TEOS) deposition, followed by photolithography and etching processes.

Next, FIGS. 6J and 6K show processes used to form the buried diffusion regions 236, 238, 240, and 242. FIG. 6J shows a mask layer 270 that is first selectively formed using photolithography. Next, ion implantation is used to diffusion exposed regions to form the N+ buried diffusion regions 238 and 242. Similarly, FIG. 6K shows a mask layer 272 that is first selectively formed using photolithography, followed by ion implantation for diffusion of exposed regions to form the P+ buried diffusion regions 236 and 240.

FIGS. 6L and 6M show metallization processes along section lines A-A, while FIGS. 6N and 6O show metallization processes along section lines B-B. The metallization processes can include ILD deposition, photolithography, and etching to produce the structures shown in FIGS. 6L and 6N, followed by metal deposition, photolithography, and etching to produce the structures shown in FIGS. 6M and 6O.

While various embodiments in accordance with the disclosed principles have been described above, it should be understood that they have been presented by way of example only, and are not limiting. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

What is claimed is:

1. A semiconductor device comprising:
a semiconductor substrate;
a lateral semiconductor diode formed in a surface region of the semiconductor substrate, the diode having a cathode electrode and an anode electrode;
a field insulation structure disposed between the cathode and anode electrodes; and
a polysilicon resistor formed over the field insulation structure and between the cathode and anode electrodes, the polysilicon resistor being electrically connected to the cathode electrode and electrically insulated from the anode electrode.

2. The semiconductor device of claim 1, wherein the polysilicon resistor is formed on an upper surface of the field insulation structure to at least partially surround the cathode electrode.

3. The semiconductor device of claim 2, wherein the polysilicon resistor includes a plurality of semicircular segments concentrically arranged between the cathode and anode electrodes.

4. The semiconductor device of claim 3, wherein the segments include at least one innermost segment that is electrically connected to the cathode electrode.

5. The semiconductor device of claim 4, wherein adjacent segments are electrically connected so as to form a continuous polysilicon resistor structure from the cathode electrode to a terminal external to the semiconductor diode.

6. The semiconductor device of claim 1, wherein the anode electrode includes a circular structure surrounding the cathode electrode.

7. The semiconductor device of claim 1, wherein the polysilicon resistor includes a plurality of semicircular segments arranged in a coaxial pattern, the semicircular segments being surrounded by the anode electrode.

8. A method of manufacturing a semiconductor device, the method comprising:
providing a semiconductor substrate;
forming a lateral semiconductor diode in a surface region of the semiconductor substrate, the forming of the lateral semiconductor diode including forming a cathode electrode and forming an anode electrode;
forming a field insulation structure between the cathode and anode electrodes; and
forming a polysilicon resistor over the field insulation structure and between the cathode and anode electrodes, the forming of the polysilicon resistor including forming the polysilicon resistor to be electrically connected to the cathode electrode and electrically insulated from the anode electrode.

9. The method of claim 8, wherein the forming of the polysilicon resistor includes forming the polysilicon resistor on an upper surface of the field insulation structure to at least partially surround the cathode electrode.

10. The method of claim 9, wherein the forming of the polysilicon resistor includes forming the polysilicon resistor to includes a plurality of semicircular segments concentrically arranged between the cathode and anode electrodes.

11. The method of claim 10, wherein the forming of the polysilicon resistor includes forming the segments to include at least one innermost segment that is electrically connected to the cathode electrode.

12. The method of claim 11, wherein the forming of the polysilicon resistor includes forming adjacent segments to be electrically connected so as to form a continuous polysilicon resistor structure from the cathode electrode to a terminal external to the semiconductor diode.

13. The method of claim 8, wherein the forming of the anode electrode includes forming a circular structure as the anode electrode surrounding the cathode electrode.

14. The method of claim 8, wherein the forming of the polysilicon resistor includes forming the polysilicon resistor to include a plurality of semicircular segments arranged in a coaxial pattern, the semicircular segments being surrounded by the anode electrode.
